(19) United States
(12) Patent Application Publication
(10) Pub. No.: US 2012/0112041 A1
(43) Pub. Date: May 10, 2012

(54) METHOD AND SYSTEM FOR AN IMAGE SENSOR CAPABLE OF PERFORMING SELECTIVE ANALOG BINNING OPERATION

(75) Inventor: Kwang Jun CHO, Seoul (KR)

(73) Assignee: HYNIX SEMICONDUCTOR INC., Icheon-si (KR)

(21) Appl. No.: 13/293,367

(22) Filed: Nov. 10, 2011

(30) Foreign Application Priority Data
Nov. 10, 2010 (KR) 10-2010-0111661

(51) Int. Cl. H01L 27/146

(52) U.S. Cl. 250/208.1

(57) ABSTRACT

Provided is an image sensor including a plurality of sampling units, a plurality of signal lines connected to an amplification unit; and a plurality of first switches positioned between the plurality of sampling units and the plurality of signal lines, connecting a plurality of sampling units to the plurality of signal lines when performing analog binning operation, and connecting one of the plurality of sampling units to one of the signal lines when performing a general operation.

### CROSS-REFERENCE TO RELATED APPLICATIONS

This application claims the priority of Korean Patent Application No. 10-2010-0111661 filed on Nov. 10, 2010 in the Korean Intellectual Property Office, which is incorporated herein by reference in its entirety.

### BACKGROUND OF THE INVENTION

1. Field of the Invention

The present invention relates generally to an image sensor, and more specifically to an image sensor that is capable of performing selective analog binning operation.

2. Description of the Related Art

In general, an image sensor is a device converting an external optical image signal into an electrical signal, and is widely used for various electronic products such as, for example, a mobile phone, a personal computer camera, a video camera, and a digital camera.

Therefore, an image sensor may need to support analog binning operation in preview mode, High Definition (HD) format mode, etc. for high resolution video, small pixel size display, high frame rate, or the like.

However, when an image sensor is configured as shown in FIG. 1, analog binning operation may not be possible.

With reference to FIG. 1, an image sensor may include, for example, a timing generator 100, a plurality of pixels 111 to 1mn, a plurality of correlated double sampling devices (CDSs) 201 to 20n, a plurality of CDS switches 301 to 30n, and a programmable gain amplifier (PGA) 400. Here, the plurality of CDSs 201 to 20n and the PGA 400 are connected to each other through a single signal line SL1. The PGA 400 may include, for example, capacitors 401 and 404, a current source 402, and an amplifier 403.

The image sensor in FIG. 1 has a structure in which each CDS is connected to each column in a pixel array, and signals stored in the plurality of CDSs 201 to 20n are transmitted in sequence to the PGA 400 through one signal line SL1.

However, in order to perform an analog binning operation, the PGA 400 is required to simultaneously receive multiple signals having the same color information to obtain the sum or take an average of the received signals. But in the structure of FIG. 1, it is difficult for the PGA 400 to receive multiple signals having the same color information at the same time. Therefore, an image sensor having the structure of FIG. 1 cannot perform analog binning operation.

### SUMMARY OF THE INVENTION

An aspect of the present invention provides an image sensor capable of selectively performing analog binning operation.

Another aspect of the present invention is to provide an image sensor capable of actively varying an analog binning scheme.

Another aspect of the present invention is to provide an image sensor capable of significantly reducing an offset occurring between channels by processing signals having common color information through a single signal path.

According to an aspect of the present invention, there is provided an image sensor including a plurality of sampling units, a plurality of signal lines connected to an amplification unit, and a plurality of first switches positioned between the plurality of sampling units and the plurality of signal lines, where each switch can be configured to connect a subset of the plurality of sampling units to the plurality of signal lines when performing an analog binning operation, and configured to connect one at a time the plurality of sampling units to one of the even number of signal lines when performing a general operation.

According to another aspect of the present invention, there is provided an image sensor including a plurality of signal lines connected to a plurality of sampling units and an amplification unit configured to receive at one time a plurality of sampling signals having common color information through the plurality of signal lines during a analog binning operating mode and receive at one time a single sampling signal via one of the plurality of signal lines during a general operating mode. A path control unit may be positioned between the plurality of signal lines and the amplification unit, and may be configured to connect the plurality of signal lines to the amplification unit during the analog binning operation mode, and configured to connect one of the plurality of signal lines to the amplification unit during the general operation mode.

### BRIEF DESCRIPTION OF THE DRAWINGS

The above and other aspects, features, and other advantages of the present invention will be more clearly understood from the following descriptions taken in conjunction with the accompanying drawings:

FIG. 1 is a drawing showing a configuration of an image sensor according to related art;

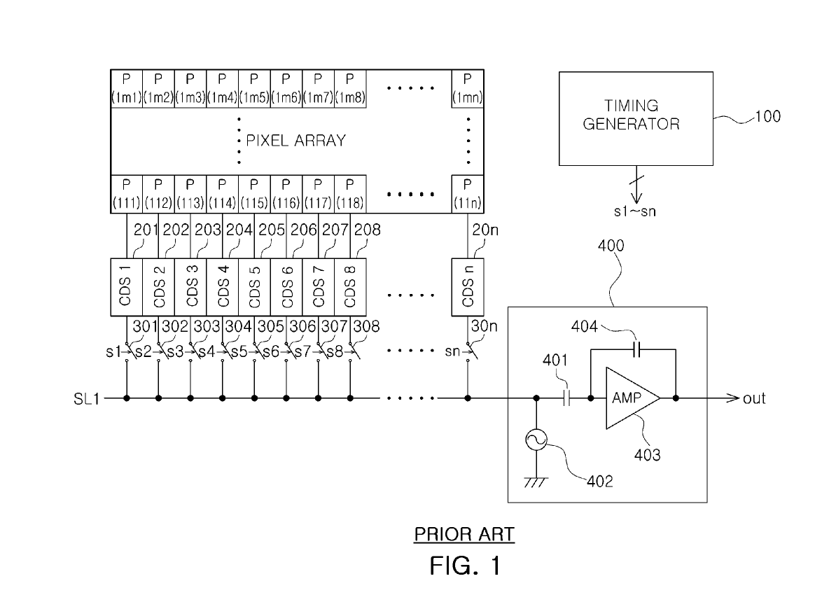

FIG. 2 is a drawing showing a configuration of an image sensor according to an embodiment of the present invention;

FIG. 3 is a drawing showing a bayer pattern that may be used with an embodiment of the present invention;

FIG. 4A is a timing diagram related to analog binning operation performed in an image sensor according to an embodiment of the present invention;

FIG. 4B is a drawing showing a configuration of an image sensor according to an embodiment of the present invention;

FIG. 4C is a timing diagram related to general operation of an image sensor according to an embodiment of the present invention;

FIG. 4D is a drawing showing a configuration of an image sensor according to an embodiment of the present invention;

FIG. 5 is a drawing showing a configuration of an image sensor according to another embodiment of the present invention; and

FIG. 6 is a drawing showing a configuration of an image sensor according to another embodiment of the present invention.

### DETAILED DESCRIPTION OF THE INVENTION

Exemplary embodiments of the present invention will be described below in more detail with reference to the accompanying drawings. The present invention may be embodied, however, in different forms and should not be construed as being limited to the embodiments set forth herein. Rather, these embodiments are provided so that this disclosure will be thorough and complete, and will fully convey the scope of the present invention to those skilled in the art.

While terms such as “first” and “second,” etc., may be used to describe various components, such components must not be understood as being limited to those terms. For example, a first component may be referred to as a second component without departing from the scope of rights of the present invention, and likewise a second component may be referred to as a first component.

An expression used in the singular encompasses the plural, unless it has a clearly different meaning in the context in which it is used. In the present disclosure, it is to be understood that terms such as “including” or “having,” etc., are intended to indicate the existence of features, numbers, operations, actions, components, parts, or combinations disclosed, and are not intended to preclude the possibility that one or more other feature, number, operation, action, component, part, or combination may exist or may be added.

Unless otherwise defined, all terms used, including technical or scientific terms, have common meanings generally understood by those with ordinary knowledge in the field of art to which the present invention belongs. Such terms are to be interpreted as having meanings equal to the contextual meanings in the relevant field of art, and are not to be interpreted as having ideal or excessively formal meanings unless clearly defined as having such in the present application.

Embodiments of the present invention will be described below in detail with reference to the accompanying drawings, where those components that are common or are in correspondence are referred to by using common reference number, regardless of the figure number, and redundant explanations are omitted.

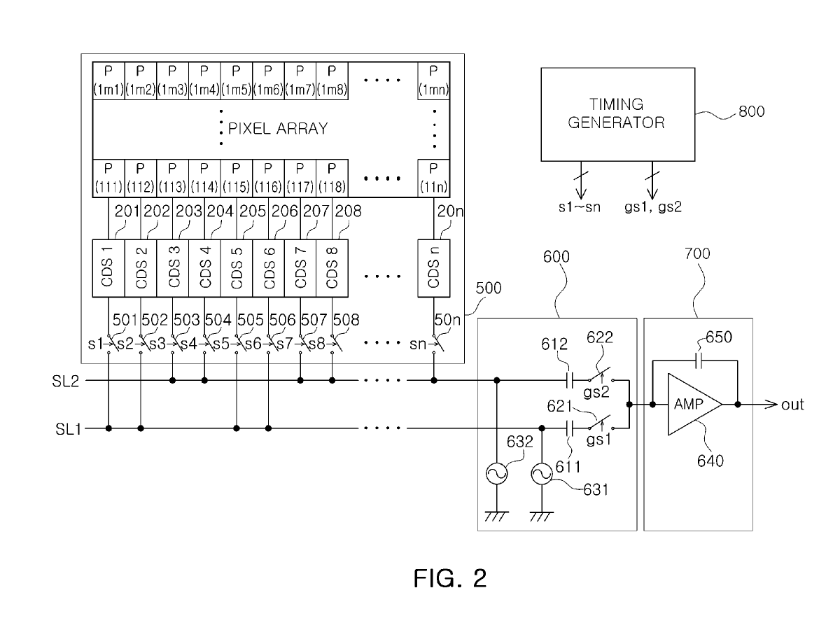

FIG. 2 is a drawing showing a configuration of an image sensor according to an embodiment of the present invention.

With reference to FIG. 2, an image sensor may include a first path control unit 500, a second path control unit 600, a programmable gain amplifier (PGA) 700, and a timing generator 800.

The first path control unit 500 may include a plurality of pixels 111 to 1mn outputting a plurality of pixel signals and a plurality of CDSs 201 to 20n performing correlated double sampling of the pixel signals to generate a plurality of sampling signals. The first path control unit 500 may further include a plurality of CDS switches 501 to 50n that enable selection of CDSs. During analog binning operation, it can be seen in FIG. 2 that, for example, CDS switches 501 and 503 may select CDSs 201 and 203, and output a signal having common color information, from among the plurality of CDSs 201 to 20n. The selected CDSs 201 and 203 may be respectively connected to signal lines SL1 and SL2. However, during general operation, only one CDS, for example, 201, may be selected from among the plurality of CDSs 201 to 20n to be connected to a particular signal line, for example, SL1. An embodiment of the invention may allow, for example, connecting an even number of CDSs to an even number of signal lines during analog binning operation.

The second path control unit 600 may connect the signal lines SL1 and SL2 to the PGA 700 when performing an analog binning operation, and may connect one of the signal lines, for example, SL1, to the PGA 700 when performing general operation.

During analog binning operation, the PGA 700 may receive the a plurality of sampling signals having common color information through the second path control unit 600 to obtain the sum of the signals, or may receive one sampling signal during general operation. The PGA 700 may then perform amplification operation on the one or more received signals.

The timing generator 800 may generate various control signals s1 to sn, gs1, and gs2 to control operation of the first and second path control units 500 and 600.

Accordingly, it can be seen that the image sensor described with respect to FIG. 2 may connect one or more CDSs 201 to 20n to the PGA 700 through a plurality of signal lines, for example, SL1 and SL2. Accordingly, analog binning operation or general operation may be selectively performed.

The second path control unit 600 may include charge capacitors 611 and 612 accumulating a signal charge corresponding to a sampling signal transmitted through each of the signal lines SL1 and SL2. The second path control unit 600 may also include PGA switches 621 and 622 adding and outputting the signal charge accumulated in the charge capacitors 611 and 612 to the PGA 700 when performing analog binning operation. During general operation, signal charge accumulated in a single charge capacitor, for example, 611, may be output to the PGA 700.

In addition, the second path control unit 600 may further include current sources 631 and 632 respectively connected to the charge capacitors 611 and 612 to improve signal characteristics of those capacitors.

The PGA 700 may include, for example, an operational amplifier 640 and a feedback capacitor 650. The PGA 700 may be any design and/or implementation satisfactory for image processing.

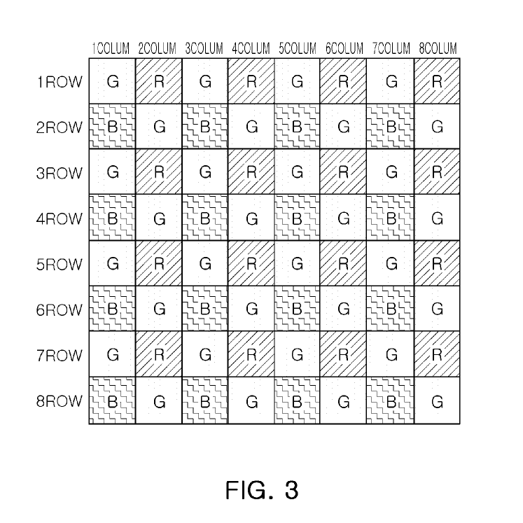

For reference, since the image sensor described above may generally be configured to have a bayer pattern shown in FIG. 3, the plurality of pixels 111 to 1mn according to an embodiment of the present invention may also be configured based on the bayer pattern.

As can be seen in FIG. 3, a first pixel and an adjacent pixel may generate pixel signals having different color information. However, it can be seen that every other pixel may generate pixel signals having common color information. Accordingly, a first CDS and an adjacent CDS may output signals having different color information, while a first CDS and a CDS separated from the first CDS by another CDS may output signals having common color information.

In order to perform analog binning operation for a color, the PGA 700 should receive signals output by some number of every other CDSs, for example, 201 and 203. Accordingly, a plurality of signals having common color information may be added to one signal.

Therefore, according to an embodiment of the present invention, as shown in FIG. 2, there may be a plurality of signal lines for analog binning operation. For example, FIG. 2 shows two signal lines SL1 and SL2. Accordingly, the CDSs 201 and 203 may be respectively connected with the signal lines SL1 and SL2 when performing analog binning operation, and the PGA 700 may receive output signals from the CDSs 201 and 203 via the signal lines SL1 and SL2 to perform analog binning operation.

Analog binning operation and general operation in the image sensor according to an embodiment of the present invention will be described in detail below.

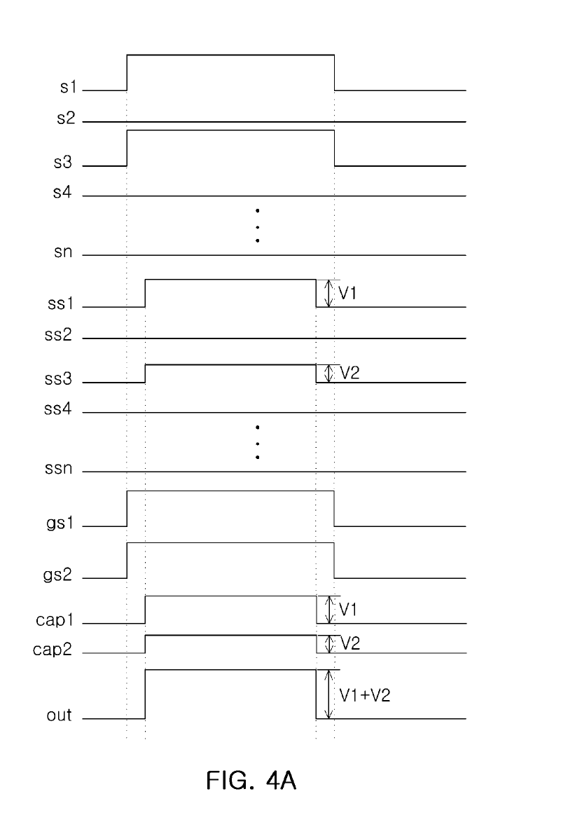

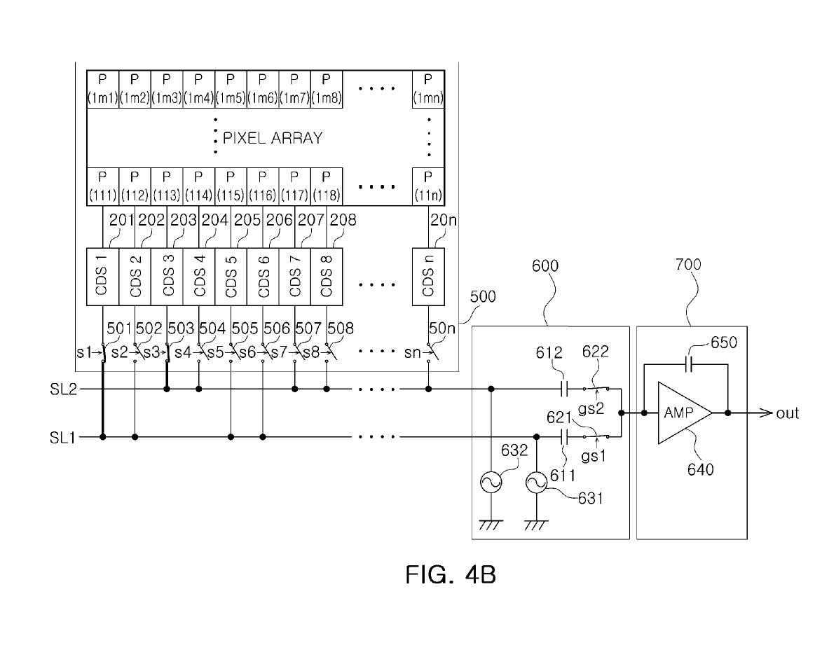

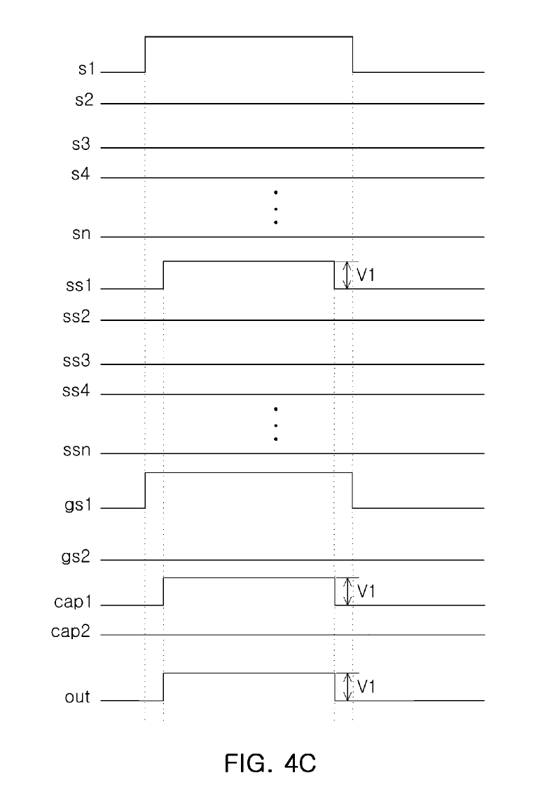

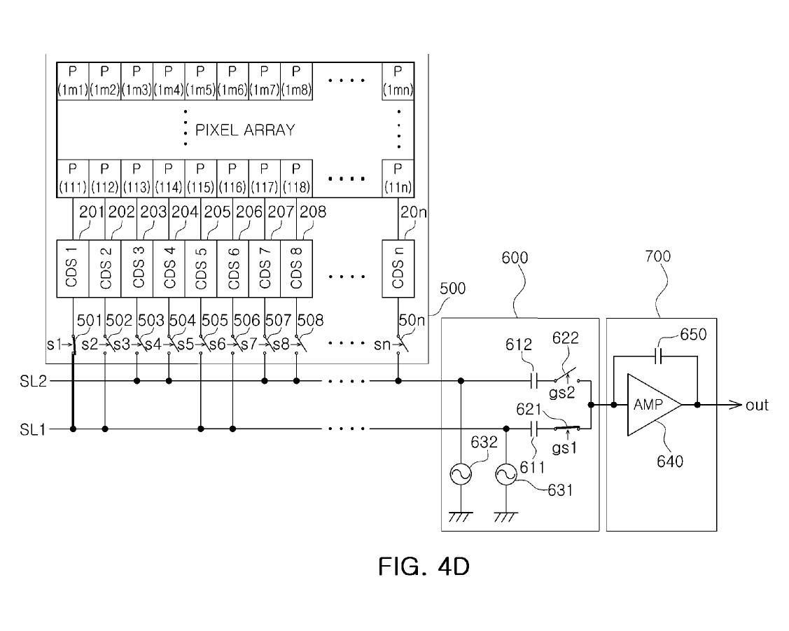

FIGS. 4A and 4B are drawings for explaining an analog binning operation performed in an image sensor according to an embodiment of the present invention.

For convenience of explanation, it is assumed that outputs from first and third CDS switches 501 and 503, having common color information, are used for analog binning operation with reference to FIGS. 4A and 4B.

First, the timing generator 800 may activate control signals s1, s3, gs1 and gs2 so as to turn on the first and third CDS switches 501 and 503 and the first and second PGA switches 621 and 622. Then, the first and third CDSs 201 and 203 may be respectively connected to the first and second charge capacitors 611 and 612 via the first and second signal lines SL1 and SL2. The first and second capacitors 611 and 612 may be commonly connected to an input terminal of the operational amplifier 640.

In this state, when the first and third CDSs 201 and 203 respectively output first and third sampling signals ss1 and ss3, the first and second charge capacitors 611 and 612 may respectively receive the output sampling signals through the first and second signal lines SL1 and SL2 to thus perform a charging operation with charges corresponding to the first and third sampling signals ss1 and ss3.

Thereafter, the operational amplifier 640 may receive the charges V1 and V2 obtained through the charging operation performed in the first and second charge capacitors 611 and 612, and may obtain the sum of the received charges V1 and V2 to generate a final output signal out that is equal to V1+V2. That is, signals output from the first and third CDSs 201 and 203 undergo the analog binning operation such that the final output signal out equal to V1+V2 is generated.

FIGS. 4C and 4D are drawings for explaining general operation in an image sensor according to an embodiment of the present invention. For convenience of explanation in FIGS. 4C and 4D, an output from the first CDS switch 501 may be assumed to be output to the PGA 700.

First, the timing generator 800 may only turn on a single switch 501 and the PGA switch 621 by only activating the control signals s1 and gs1, unlike in the analog binning operation. Accordingly, the first CDS 201 may be connected to the first signal line SL1, and only the first charge capacitor 611 positioned on the first signal line SL1 may be connected to the input terminal of the operational amplifier 640.

In this state, when the first CDS 201 outputs the first sampling signal ss1, the first charge capacitor 611 may receive the output sampling signal through the first signal line SL1 to perform a charging operation with a charge corresponding to the first sampling signal ss1.

Thereafter, the operational amplifier 640 may generate an output signal out that is equal to V1, corresponding to the charge V1 obtained through the charging operation performed in the first charge capacitor 611.

As such, an image sensor according to an embodiment of the present invention may be provided to include a plurality of signal lines and also control a connection correlation between the plurality of signal lines and the plurality of CDSs, and between the signal lines and the operational amplifier, whereby both analog binning operation and a general operation can be supported.

In particular in the case of analog binning operation, since a plurality of sampling signals having common color information are added to each other and then generated as a final output signal, the final output signal may be generated as an output signal having an increased signal value. Thus, the image sensor may provide improved image quality.

In addition, as a current source is connected to each of charge capacitors, each of the charge capacitors may be provided with a sufficient charging current. As a result, improved signal characteristics may be provided in the charge capacitors, and therefore, the image sensor may generate an output having improved signal characteristics.

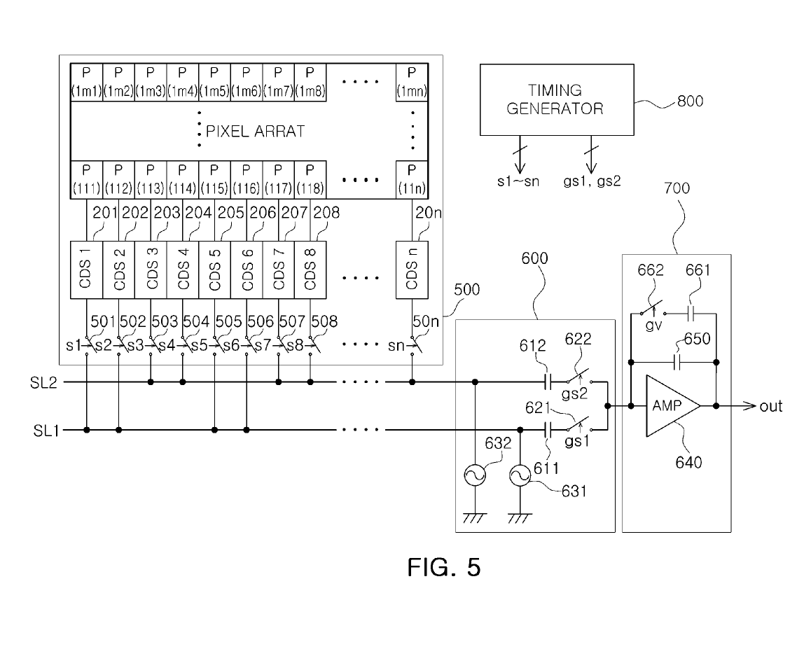

Although the image sensor is described above such that an analog binning operation is performed by a fixed gain, the image sensor may be configured as shown in FIG. 5 such that the analog binning scheme may be varied.

FIG. 5 is a drawing showing a configuration of an image sensor according to another embodiment of the present invention.

With reference to FIG. 5, the PGA 700 of the image sensor may further include a second feedback capacitor 661 connected to be parallel with the first feedback capacitor 650, and a gain control switch 662. Accordingly, the amplification gain of the operational amplifier 640 may be actively varied by switching in the second feedback capacitor 661.

Further, the timing generator 800 may additionally generate a control signal gv controlling an amplification gain of the operational amplifier 640, in addition to the control signals s1 to sn, gs1 and gs2 for controlling a connection correlation between the CDSs 201 to 50n and the signal lines SL1 and SL2 and between the charge capacitors 611 and 612 and the operational amplifier 640. That is, the control signal gv determining an analog binning scheme may be additionally provided.

Therefore, the image sensor may control a gain of the operational amplifier 640 by controlling an operation state of the gain control switch 662. That is, an amplification gain may be determined by the first feedback capacitor 650 and the second feedback capacitor 661 by turning the gain control switch 662 on, or the amplification gain may only be determined by the first feedback capacitor 650 by turning the gain control switch 662 off.

For example, when a first amplification gain has been determined by using the first feedback capacitor 650 and the second feedback capacitor 661, the operational amplifier 640 may obtain the sum of the plurality of sampling signals having common color information to thus generate a final output signal. When a second amplification gain has been determined by using only the first feedback capacitor 650, the operational amplifier 640 may take an average of the plurality of sampling signals having common color information, to thus generate a final output signal.

That is, the image sensor may obtain the sum of the sampling signals to perform an analog binning operation or take an average of the sampling signals to perform the analog binning operation, by controlling an amplification gain of the operational amplifier 640.

The image sensor may also turn the gain control switch 662 off in the case of a general operation, such that the operational amplifier 640 generates an output signal in the same manner as the embodiment of FIG. 2.

As described above, the image sensor according to another embodiment of the present invention may enable an analog binning scheme to become varied as well as performing both of the analog binning operation and the general operation. The number of different gains may be design and/or implementation dependent.

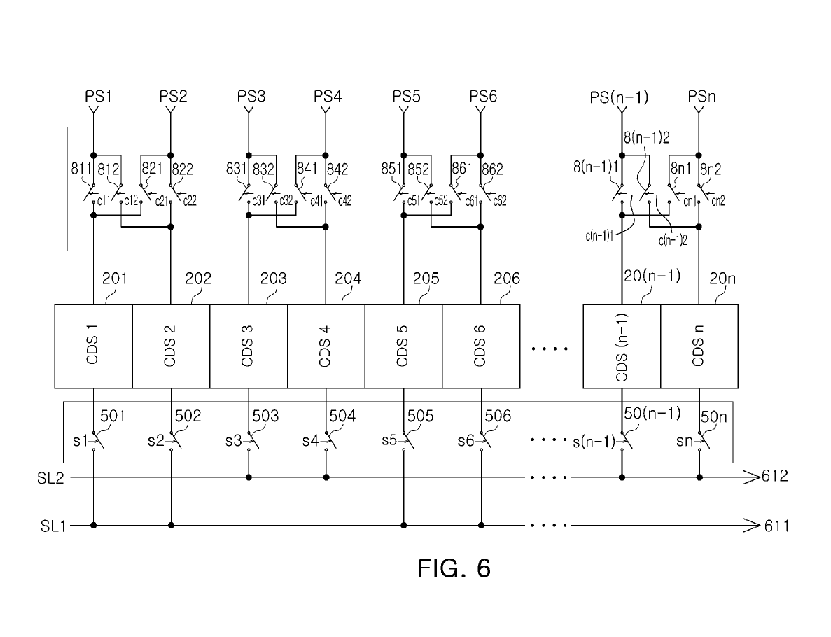

In addition, according to an embodiment of the present invention, an image sensor may be configured as shown in FIG. 6. Here, signals which are generated by pixels having common color information may be processed through a single signal path, thereby significantly reducing a channel offset occurring between signals having common color information.

FIG. 6 is a drawing showing a configuration of an image sensor according to another embodiment of the present invention.

With reference to FIG. 6, in an image sensor according to another embodiment of the present invention, it can be appreciated that a plurality of pixel switches 811 to 8n2 may be additionally positioned between a pixel array and the plurality of CDSs 201 to 20n of the image sensor configured as shown in FIG. 2 or FIG. 5. That is, in the case of the image sensor shown in FIG. 6, the plurality of pixel switches 811 to 8n2 for respectively connecting a plurality of pixel output terminals PS1 to PSn to CDSs positioned on a single column, or CDSs positioned on a column adjacent to a specific pixel, may be additionally provided.

Further, the timing generator 800 may additionally provide control signals c11 to cn2, controlling an operation of the plurality of pixel switches 811 to 8n2.

For reference, since a pixel array is configured according to a bayer pattern as described above, pixels having common color information may be positioned at every other pixel in a row. However, in the case of a G color, pixels having common color information may be also provided diagonally adjacent in rows above and below a specific pixel.

Further, as described above, at the time of analog binning operation, common color signals generated by the pixels positioned on a row may be output by a plurality of pixels at the same time, but at the time of general operation, signals are output in sequence.

Thus, the timing generator 800 of FIG. 6 may control the plurality of pixel switches 811 to 8n2 such that output signals from common color pixels positioned on adjacent rows are simultaneously output to the CDSs 201 to 20n when the image sensor performs an analog binning operation. That is, a pixel output terminal PS1˜PSn and a CDS 201˜20n positioned on a single column may be connected to each other through each of the plurality of pixel switches 811 to 8n2.

On the other hand, in a case in which an image sensor performs a general operation, the timing generator 800 may control the plurality of pixel switches 811 to 8n2 such that signals having common color information, generated by common color pixels may be supplied to a single CDS 201˜20n. As an example, by appropriately connecting a pixel output terminal, for example, PS1 on an odd row to the CDS 201, and a pixel output terminal, for example, PS2, on an even row to the CDS 201, signals which are generated by pixels positioned on rows and columns adjacent to a specific pixel and which have G color information, may be provided to the PGA 700 through a single signal path, for example, the first CDS 201, the first CDS switch 501, and the first signal line SL1.

As described above, according to an embodiment of the present invention, pixel signals which are generated by pixels positioned on rows and columns adjacent to a specific pixel, and which have common color information, may be transmitted to the PGA through a single CDS, a single CDS switch and a single signal line, whereby a channel offset occurring between signals having common color information may be significantly reduced.

As set forth above, an image sensor according to an embodiment of the present invention may perform both a general operation and an analog binning operation, and in particular, at the time of an analog binning operation, a plurality of sampling signals having common color information may be added to each other to generate a final output signal, whereby an improved image quality may be provided in the image sensor. In addition, a current source may be connected to each charge capacitor to improve signal characteristics.

Further, an amplification gain of a PGA may be controlled such that it can be determined as to whether an analog binning operation is performed by an addition scheme or by an averaging scheme. That is, since an analog binning scheme may be adjusted, an image sensor may be applied to various related fields.

In addition, operation reliability in an image sensor may be enhanced by significantly reducing a defect in which signals having common color information have different channel offsets during general operation.

While the present invention has been shown and described in connection with the embodiments, it will be apparent to those skilled in the art that modifications and variations can be made without departing from the spirit and scope of the invention as defined by the appended claims.

What is claimed is:

1. An image sensor comprising:
a plurality of sampling units;
a plurality of signal lines connected to an amplification unit; and
a plurality of first switches positioned between the plurality of sampling units and the plurality of signal lines, wherein each first switch can be configured to connect a subset of the plurality of sampling units to the plurality of signal lines when performing an analog binning operation, and configured to connect one at a time the plurality of sampling units to one of the plurality of signal lines when performing a general operation.

2. The image sensor of claim 1, wherein the number of sampling units output a sampling signal having common color information.

3. The image sensor of claim 1, wherein there is an even number of signal lines.

4. The image sensor of claim 1, further comprising a plurality of second switches configured to sequentially connect pixels in different rows having a common color information to one of the plurality of sampling units when performing the general operation.

5. An image sensor comprising:
a plurality of signal lines connected to a plurality of sampling units;
an amplification unit configured to receive at one time a plurality of sampling signals having common color information through the plurality of signal lines during a analog binning operating mode, and receive at one time one sampling signal via one of the plurality of signal lines during a general operating mode; and
a path control unit positioned between the plurality of signal lines and the amplification unit, configured to connect the plurality of signal lines to the amplification unit during the analog binning operating mode, and configured to connect one of the plurality of signal lines to the amplification unit during the general operating mode.

6. The image sensor of claim 5, wherein the path control unit includes:
a plurality of capacitors positioned on each of the plurality of signal lines and configured to accumulate each signal charge of the plurality of sampling signals transmitted through each of the plurality of signal lines; and
a plurality of amplification switches positioned between each of the plurality of capacitors and an input terminal of the amplification unit configured to connect corresponding capacitors to the input terminal of the amplification unit during the analog binning operation mode, and to connect one of the plurality of capacitors to the input terminal of the amplification unit during the general operation mode.

7. The image sensor of claim 6, wherein the path control unit further includes a plurality of current sources for each of the plurality of capacitors.

8. The image sensor of claim 6, wherein the amplification unit includes:
an operational amplifier having an input terminal connected to the plurality of amplification switches; and
a first feedback capacitor connected between the input and output terminals of the operational amplifier.

9. The image sensor of claim 8, wherein the amplification unit further includes:
a second feedback capacitor enabled to be connected between the input and output terminals of the operational amplifier in parallel to the first feedback capacitor; and
a gain control switch such that when turned on it configures the second feedback capacitor to provide feedback signal between the input and output terminals of the operational amplifier.

10. The image sensor of claim 5, wherein there is an even number of signal lines.
